(19) United States
(12) Patent Application Publication
(10) Pub. No.: US 2006/0220676 A1
(43) Pub. Date: Oct. 5, 2006

(54) Semiconductor device

(75) Inventor: Naoki Kanazawa, Chiba (JP)

Correspondence Address: OLIFF & BERRIDGE, PLC, P.O. BOX 19928, ALEXANDRIA, VA, 22320, US

(73) Assignee: Kawasaki Microelectronics, Inc., Chiba-shi (JP)

(21) Appl. No.: 11/393,851

(22) Filed: Mar. 31, 2006

(30) Foreign Application Priority Data
Apr. 5, 2005 (JP) 2005-108338

(51) Int. Cl. H03K 19/003

(52) U.S. Cl. 326/33

(57) ABSTRACT

A semiconductor device includes an internal circuit having a data holding circuit, and at least one leakage current cut-off circuit provided between the internal circuit and a power supply or a ground, and is capable of preventing data in the data holding circuit from being destroyed. A ground-side cut-off circuit includes a switch and a control circuit. The switch electrically connects or cuts a path between a source of a ground-side transistor of the internal circuit and the ground. The control circuit turns off the switch upon detecting that source potential of the ground-side transistor is substantially equal to that of the ground. Upon detecting that the source potential of the ground-side transistor rises to a predetermined potential lower than a potential necessary for holding the data in the data holding circuit, the control circuit turns on the switch.

### BACKGROUND

Exemplary embodiments of the present invention relate to a technique for reducing power consumption of semiconductor devices.

As miniaturization in semiconductor manufacturing processes advances, even if a transistor is in the OFF state, an off-leakage current (a current that flows when the transistor is in the OFF state) flows through paths between a gate and a source, between the gate and a drain, and between the source and the drain. The off-leakage current (hereinafter, referred to as “leakage current”) increases static current consumption IDDS. Accordingly, problems regarding the increase in the static current consumption are emerging.

For example, as shown in FIG. 6, an internal circuit 48 includes two inverters 50 and 52 that are connected in series. A low level signal that is input to the internal circuit 48 turns on a P-channel metal-oxide semiconductor transistor (hereinafter, referred to as “PMOS”) 54 of the inverter 50, and turns off an N-channel metal-oxide semiconductor transistor (hereinafter, referred to as “NMOS”) 56. Accordingly, an output signal of the inverter 50 reaches a high level. Also, at this time, a PMOS 58 and an NMOS 60 of the inverter 52 are turned off and on, respectively. Accordingly, an output signal of the inverter 52 reaches a low level.

As described above, since the NMOS 56 of the inverter 50 is in the OFF state, a path of a current that flows from a power supply to a ground should be cut by the NMOS 56. However, as miniaturization in the manufacturing processes advances, a leakage current that flows from the power supply to the ground through the PMOS 54 and the NMOS 56, which are in the ON and OFF states, respectively, has been increasing. Likewise, the same phenomenon occurs in the inverter 52.

To reduce leakage currents, it has been suggested that leakage current cut-off circuits for cutting paths through which the leakage currents flow should be provided between sources of transistors included in an internal circuit and a power supply as well as between sources of transistors and a ground. When the internal circuit is not in an operational mode, these leakage current cut-off circuits electrically cut the paths between the power supply and the sources of the transistors disposed near the power supply (power-supply-side transistors) and between the sources of the transistors disposed near the ground (ground-side transistors) and the ground. This eliminates the paths of the leakage currents that flow from the power supply to the ground, thereby reducing static current consumption IDDS.

More specifically, a method for reducing static current consumption IDDS has been disclosed (see, for example, Tadayoshi Enomoto, “Low Power Techniques Sub-100-nm CMOS LSIs”, Technical Report of IEICE, Institute of Electronics, Information and Communication Engineers, ICD 2004-16 (May, 2004), pp. 15-20, FIG. 10.1 (a)). In this disclosure, leakage current cut-off transistors are connected between a power supply and sources of power-supply-side transistors of an internal circuit, and between sources of ground-side transistors and a ground. Since the cut-off transistors are configured to have higher threshold voltage values than transistors included in the internal circuit, the cut-off transistors are less likely to be turned on. When the internal circuit is not in an operational mode, turning off the cut-off transistors cuts paths of leakage currents, thereby reducing the static current consumption IDDS.

In another method for reducing leakage currents, leakage current cut-off transistors having threshold voltage values equivalent to those of transistors in an internal circuit are used. The gate potential of the cut-off transistor at the time of being turned off is configured to be lower than that of transistors in the internal circuit at the time of being turned off. This increases off-resistance between a source and a drain of the cut-off transistor, thereby reducing the leakage currents.

For example, as shown in FIG. 7, when a leakage current cut-off circuit is disposed near ground, an NMOS 62, namely a leakage current cut-off transistor, is connected between a source GND′ of transistors in an internal circuit 48 (hereinafter simply referred to as “source GND′”) and a ground GND. When the internal circuit 48 is not in an operational mode, the gate potential of the NMOS 62 is set to be lower than a low potential level of the transistors in internal circuit 48, i.e., 0 V, using a step-down circuit 64, and the NMOS 62 is turned off.

This makes off-resistance between a source and a drain of the NMOS 62, i.e., the resistance when the NMOS 62 is in the OFF state, greater than that of the NMOS 62 when the low potential level, 0 V, is input to the gate of the NMOS 62. Accordingly, the leakage current is reduced.

However, when the path of the leakage current between the power supply and the sources of the power-supply-side transistors in the internal circuit, and between the sources of the ground-side transistors and the ground are cut, floating occurs at internal nodes of the internal circuit. If the internal circuit is constituted by a typical logic circuit, the internal circuit operates normally by turning on the cut-off transistor when restarting the operation of the internal circuit. However, as shown in FIG. 8, if the internal circuit includes data holding circuits 66, such as latch circuits, data stored in the data holding circuits 66 may be destroyed due to the floating that occurred at a source GND′.

Methods for preventing the data destruction have been offered. In one method, for example, a semiconductor chip is configured to include an area for disposing a circuit to which a leakage current cut-off circuit is not applied. A data holding circuit is disposed in this area and holds data therein. In another method, an extra storage device is provided outside a semiconductor chip. When the internal circuit is not in the operational mode, the data held in the data holding circuits 66 is temporarily stored in the storage device. When restarting the operation of the internal circuit, the stored data is written back to the data holding circuits 66.

However, the above-described methods require the extra area for disposing the data holding circuit and the extra storage device. Accordingly, there is a disadvantage in terms of semiconductor device size. Also, when the leakage current cut-off circuit is not applied to the data holding circuit, the leakage current in the data holding circuit cannot be reduced.

### SUMMARY

Accordingly, in various exemplary embodiments of the present invention, the above-described disadvantages of the related art are addressed. More specifically, the various exemplary embodiments of the present invention provide a semiconductor device having at least one leakage current cut-off circuit that is capable of preventing data destruction without providing an extra area for disposing a data holding circuit or an extra storage device.

According to an exemplary embodiment of the present invention, a semiconductor device includes an internal circuit that has a data holding circuit, and at least one leakage current cut-off circuit which electrically connects or cuts at least one of a path between a power supply and the internal circuit, and a path between a ground and the internal circuit on the basis of a control signal. The leakage current cut-off circuit for electrically connecting or cutting the path between the power supply and the internal circuit includes a first switch and a first control circuit. The first switch electrically connects or cuts a path between the power supply and a source of a power-supply-side transistor of the internal circuit, on the basis of a first detection signal. The first control circuit, when the internal circuit is out of an operational mode, upon detecting that a potential at the source of the power-supply-side transistor has become substantially equal to a potential of the power supply, causes the first detection signal to become a first state such that the first switch is put into a cut-off state. Further, the first control circuit, upon detecting that the potential at the source of the power-supply-side transistor has dropped to a predetermined potential that is higher than a potential necessary for holding data in the data holding circuit, causes the first detection signal to become a second state such that the first switch is put into a connected state. Whereas, when the internal circuit is in the operational mode, the first control circuit causes the first detection signal to become the second state such that the first switch is put into the connected state. The leakage current cut-off circuit for electrically connecting or cutting the path between the ground and the internal circuit includes a second switch and a second control circuit. The second switch electrically connects or cuts a path between a source of a ground-side transistor of the internal circuit and the ground on the basis of a second detection signal. The second control circuit, when the internal circuit is out of the operational mode, upon detecting that a potential at the source of the ground-side transistor has become substantially equal to a potential of the ground, causes the second detection signal to become the first state such that the second switch is put into the cut-off state. Further, the second control circuit, upon detecting that the potential at the source of the ground-side transistor has risen to a predetermined potential that is lower than a potential necessary for holding the data in the data holding circuit, causes the second detection signal to become the second state such that the second switch is put into the connected state. Whereas, when the internal circuit is in the operational mode, the second control circuit causes the second detection signal to become the second state such that the second switch is put into the connected state.

In this exemplary embodiment of a semiconductor device, the first switch includes a step-up circuit for receiving the first detection signal and outputting a signal having a stepped-up potential that is equal to or higher than that of the power supply. The first switch also includes a first transistor for electrically connecting or cutting the path between the power supply and the source of the power-supply-side transistor on the basis of an output signal of the step-up circuit. The second switch includes a step-down circuit for receiving the second detection signal and outputting a signal having a stepped-down potential that is equal to or lower than the potential of the ground. The second switch also includes a second transistor for electrically connecting or cutting the path between the source of the ground-side transistor and the ground on the basis of an output signal of the step-down circuit.

Alternatively, the first switch may include a first transistor, having a threshold voltage that is higher than that of the power-supply-side transistor, for electrically connecting or cutting the path between the power supply and the source of the power-supply-side transistor on the basis of the first detection signal. The second switch may include a second transistor, having a threshold voltage that is higher than that of the ground-side transistor, for electrically connecting or cutting the path between the source of the ground-side transistor and the ground on the basis of the second detection signal.

Also, in an exemplary embodiment, the internal circuit of the semiconductor device may be divided into a predetermined number of blocks, and at least one leakage current cut-off circuit for electrically connecting or cutting at least one of the path between the power supply and the internal circuit, and the path between the ground and the internal circuit, may be disposed in each of the blocks. The semiconductor device may further include a holding circuit for holding history data of the first detection signal and the second detection signal output from the corresponding leakage current cut-off circuits in each of the blocks. The first control circuit in each of the blocks may perform a control operation such that the first switch is put into the connected state or the cut-off state on the basis of the history data of the first detection signal, held in the holding circuit, of the corresponding block. The second control circuit in each of the blocks may perform a control operation such that the second switch is put into the connected state or the cut-off state on the basis of the history data of the second detection signal, held in the holding circuit, of the corresponding block.

According to another exemplary embodiment of the present invention, a semiconductor device includes an internal circuit having a data holding circuit, and at least one leakage current cut-off circuit which electrically connects or cuts at least one of a path between a power supply and the internal circuit and a path between a ground and the internal circuit on the basis of a control signal.

The leakage current cut-off circuit for electrically connecting or cutting the path between the power supply and the internal circuit includes a first switch and a first control circuit. The first switch electrically connects or cuts a path between the power supply and a source of a power-supply-side transistor of the internal circuit on the basis of a first pulse signal. The first control circuit, when the internal circuit is out of an operational mode, puts the first switch into a connected state for a first predetermined time period at first predetermined time intervals. The first time interval is shorter than the time required for a potential at the source of the power-supply-side transistor to drop to a predetermined potential that is higher than a potential necessary for holding data in the data holding circuit after the first control circuit causes the first pulse signal to become a first state such that the first switch is put into a cut-off state. The first time period is equivalent to the time required for the potential at the source of the power-supply-side transistor to become substantially equal to a potential of the power supply after the first control circuit causes the first pulse signal to become a second state. Whereas when the internal circuit is in the operational mode, the first control circuit causes the first pulse signal to become the second state such that the first switch is put into the connected state.

The leakage current cut-off circuit for electrically connecting or cutting the path between the ground and the internal circuit includes a second switch and a second control circuit. The second switch electrically connects or cuts a path between a source of a ground-side transistor of the internal circuit and the ground on the basis of a second pulse signal. The second control circuit, when the internal circuit is out of the operational mode, puts the second switch into the connected state for a second predetermined time period at second predetermined time intervals. The second predetermined time interval is shorter than the time required for a potential at the source of the ground-side transistor to rise to a predetermined potential that is lower than a potential necessary for holding the data in the data holding circuit after the second control circuit causes the second pulse signal to become the first state such that the second switch is put into the cut-off state. The second time period is equivalent to the time required for the potential at the source of the ground-side transistor to become substantially equal to a potential of the ground after the second control circuit causes the second pulse signal to become the second state. When the internal circuit is in the operational mode, the second control signal causes the second pulse signal to become the second state such that the second switch is put into the connected state.

In this exemplary embodiment, the first switch of the semiconductor device includes a step-up circuit and a first transistor. The step-up circuits receives the first pulse signal and outputs a signal having a stepped-up potential that is equal to or higher than that of the power supply. The first transistor electrically connects or cuts the path between the power supply and the source of the power-supply-side transistor on the basis of an output signal of the step-up circuit. The second switch includes a step-down circuit and a second transistor. The step-down circuit receives the second pulse signal and outputs a signal having a stepped-down potential that is equal to or lower than that of the ground. The second transistor electrically connects or cuts the path between the source of the ground-side transistor and the ground on the basis of an output signal of the step-down circuit.

Alternatively, the first switch may include a first transistor, having threshold voltage higher than that of the power-supply-side transistor, for electrically connecting or cutting the path between the power supply and the source of the power-supply-side transistor on the basis of the first pulse signal. The second switch may include a second transistor, having threshold voltage higher than that of the ground-side transistor, for electrically connecting or cutting the path between the source of the ground-side transistor and the ground on the basis of the second pulse signal.

In an exemplary embodiment of the present invention, when the internal circuit of the semiconductor device is not in operational mode, the path between the sources of the transistors in the internal circuit and the power supply or the ground is electrically connected by detecting the potential at the sources of the transistors in the internal circuit or at predetermined time intervals after cutting the path. This prevents the data held in the data holding circuits from being destroyed with the leakage current cut-off circuits, without providing an extra area for disposing the data holding circuit or an extra storage device. Additionally, the amount of off-leakage current that flows when the internal circuit is not in the operational mode can be reduced.

### BRIEF DESCRIPTION OF THE DRAWINGS

FIG. 1 is a schematic diagram showing a semiconductor device according to an embodiment of the present invention;

FIG. 2 is a circuit diagram of a source potential comparator circuit shown in FIG. 1;

FIG. 3 is a graph showing a change in potential at a source GND′ shown in FIG. 1;

FIG. 4 is a schematic diagram showing a semiconductor device according to another embodiment of the present invention;

FIG. 5 is a schematic diagram showing a semiconductor device according to another embodiment of the present invention;

FIG. 6 is a schematic diagram showing a path of a leakage current according to the related art;

FIG. 7 is a schematic diagram showing a leakage current cut-off circuit and an operation thereof according to the related art; and

FIG. 8 is a schematic diagram showing a disadvantage of a leakage current cut-off circuit according to the related art.

### DESCRIPTION OF THE EXEMPLARY EMBODIMENTS

Semiconductor devices according to various exemplary embodiments of the present invention will be described in detail below with reference to the accompanying drawings.

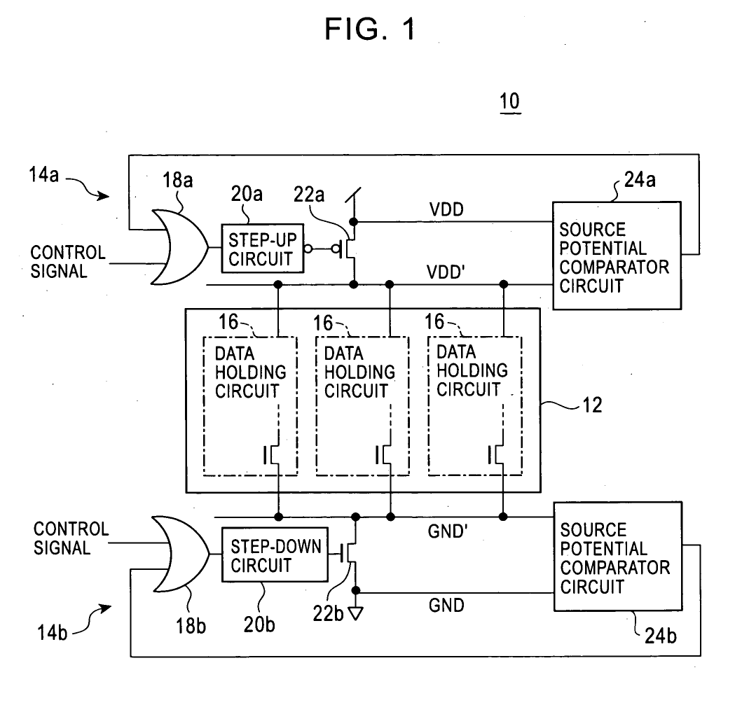

FIG. 1 is a schematic diagram showing a semiconductor device according to an exemplary embodiment of the present invention. A semiconductor device 10 shown in FIG. 1 includes an internal circuit 12, and leakage current cut-off circuits 14a and 14b that are disposed near a power supply and a ground, respectively. The internal circuit includes data holding circuits 16, such as latch circuits.

The internal circuit 12 conceptually illustrates a circuit that implements essential functions of the semiconductor device 10. In the embodiment of FIG. 1, the internal circuit 12 includes three data holding circuits 16. However, the configuration of the internal circuit 12 is not limited to this embodiment.

According to the embodiment of FIG. 1 in the semiconductor device 10, when the internal circuit 12 is in an operational mode (when paths of leakage currents are not cut), a control signal is set to a high level. When the internal circuit 12 is not in the operational mode (when the paths of the leakage currents are cut), the control signal is set to a low level.

The leakage current cut-off circuit 14a, disposed near the power supply, includes an OR circuit 18a, a step-up circuit 20a, a PMOS 22a, and a source potential comparator circuit 24a. On the basis of the control signal, the leakage current cut-off circuit 14a electrically connects or cuts a path between a power supply VDD and a source VDD′ of transistors (hereinafter, simply referred to as “source VDD′”), disposed near the power supply (power-supply-side), that are included in the internal circuit 12.

The OR circuit 18a performs a logical OR operation on the control signal and an output signal of the source potential comparator circuit 24a. An output signal of the OR circuit 18a (a first detection signal of the present invention) is input to the step-up circuit 20a.

The step-up circuit 20a receives the output signal of the OR circuit 18a and outputs a signal having a stepped-up potential that is equal to or higher than the potential of the power supply VDD. More specifically, when the output signal of the OR circuit 18a is at the high level, the step-up circuit 20a outputs a low level signal whose potential is equivalent to the potential of the ground GND. When the output signal of the OR circuit 18a is at the low level, the step-up circuit 20a outputs a high level signal whose potential is a predetermined value higher than the potential of the power supply VDD. An output signal of the step-up circuit 20a is input to a gate of the PMOS 22a.

In the above-described configuration, the output signal of the OR circuit 18a is inverted by the step-up circuit 20a and the inverted signal is output from the step-up circuit. Alternatively, a configuration in which the inverted signal of the output signal of the OR circuit 18a is stepped up by the step-up circuit 20a may be employed.

The PMOS 22a, i.e., a cut-off transistor for cutting the path of the leakage current, is connected between the power supply VDD and the source VDD′ of the power-supply-side transistors in the internal circuit 12. When the output signal of the step-up circuit 20a is at the low level, the PMOS 22a is turned on to electrically connect the path between the power supply VDD and the source VDD′. When the output signal of the step-up circuit 20a is at the high level, the PMOS 22a is turned off to electrically cut the path between the power supply VDD and the source VDD′.

When the internal circuit 12 is not in the operational mode, the source potential comparator circuit 24a compares the potential of the power supply VDD with the potential at the source VDD′. Upon detecting that the potential at the source VDD′ has become substantially equal to the potential of the power supply VDD, the source potential comparator circuit 24a outputs a low level signal. Upon detecting that the potential at the source VDD′ has dropped to a predetermined potential that is higher than a potential necessary for holding data in the data holding circuits 16, the source potential comparator circuit 24a outputs a high level signal.

On the other hand, the leakage current cut-off circuit 14b disposed near the ground includes an OR circuit 18b, a step-down circuit 20b, an NMOS 22b, and a source potential comparator circuit 24b. On the basis of a control signal, the leakage current cut-off circuit 14b electrically connects or cuts a path between a ground GND and a source GND′ of transistors (hereinafter, simple referred to as “source GND′”), disposed near the ground (ground-side), that are included in the internal circuit 12.

The OR circuit 18b performs a logical OR operation on the control signal and an output signal of the source potential comparator circuit 24b. An output signal of the OR circuit 18b (a second detection signal of the present invention) is input to the step-down circuit 20b.

The step-down circuit 20b receives the output signal of the OR circuit 18b and outputs a signal having a stepped-down potential that is equal to or lower than the potential of the ground GND. More specifically, when the output signal of the OR circuit 18b is at the high level, the step-down circuit 20b outputs a high level signal whose potential is equivalent to the potential of the power supply VDD. When the output signal of the OR circuit 18b is at the low level, the step-down circuit 20b outputs a low level signal whose potential is a predetermined value lower than the potential of the ground GND. An output signal of the step-down circuit 20b is input to a gate of the NMOS 22b.

The NMOS 22b, i.e., a cut-off transistor for cutting a path of the leakage current, is connected between the source GND′ of the ground-side transistors in the internal circuit 12 and the ground GND. When the output signal of the step-down circuit 20b is at the high level, the NMOS 22b is turned on to electrically connect the path between the source GND′ and the ground GND. When the output signal of the step-down circuit 20b is at the low level, the NMOS 22b is turned off to electrically cut the path between the source GND′ and the ground GND.

When the internal circuit 12 is not in the operational mode, the source potential comparator circuit 24b compares the potential at the source GND′ and the potential of the ground GND. Upon detecting that the potential at the source GND′ has become substantially equal to the potential of the ground GND, the source potential comparator circuit 24b outputs a low level signal. Upon detecting that the potential at the source GND′ has risen to a predetermined potential that is lower than the potential necessary for holding the data in the data holding circuits 16, the source potential comparator circuit 24b outputs a high level signal.

The OR circuit 18a and the source potential comparator circuit 24a constitute a first control circuit of the exemplary embodiments of the present invention. The OR circuit 18b and the source potential comparator circuit 24b constitute a second control circuit of the exemplary embodiments of the present invention. Also, the step-up circuit 20a and the PMOS 22a constitute a first switch of the exemplary embodiments of the present invention. The step-down circuit 20b and the NMOS 22b constitute a second switch of the exemplary embodiments of the present invention. The first and second control circuits and the first and second switches are not limited to the configuration shown in FIG. 1. That is, various configurations can be applied in order to implement similar functions of the exemplary embodiments.

A description will now be made only on the source potential comparator circuit 24b for ease of explanation.

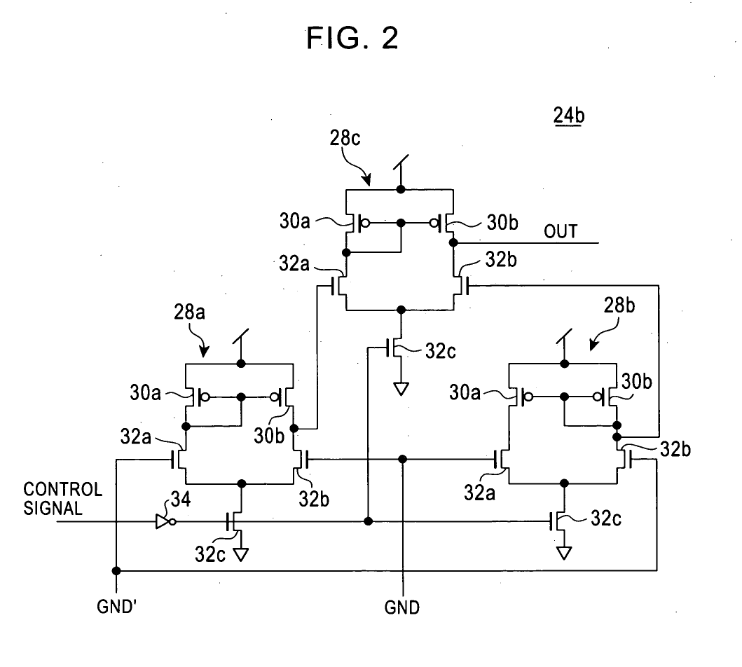

FIG. 2 is a circuit diagram of the source potential comparator circuit shown in FIG. 1. As shown in FIG. 2, the source potential comparator circuit 24b includes three current mirror sense amplifiers (hereinafter, simply referred to as “sense amplifiers”) 28a, 28b, and 28c.

The sense amplifier 28a includes two PMOSs 30a and 30b, and three NMOSs 32a, 32b, and 32c.

Sources of the PMOSs 30a and 30b are connected to a power supply. Gates of the PMOSs 30a and 30b are connected to a drain of the PMOS 30a. Drains of the NMOS 32a and 32b are connected to drains of the PMOS 30a and 30b, respectively. Sources of the NMOS 32a and 32b are connected to a drain of the NMOS 32c. A source of the NMOS 32c is connected to the ground. The sense amplifiers 28b and 28c also have the same configuration.

Additionally, gates of the NMOS 32a and the NMOS 32b, in the sense amplifier 28a, are connected to the source GND′ of the transistors in the internal circuit 12 and the ground GND, respectively. In contrast, gates of the NMOS 32a and the NMOS 32b, in the sense amplifier 28b, are connected to the ground GND and the source GND′, respectively.

Gates of the NMOS 32a and NMOS 32b, in the sense amplifier 28c, are connected to the drain of the PMOS 30b, in the sense amplifier 28a, and the drain of the PMOS 30b in the sense amplifier 28b, respectively. Also, the control signal is inverted by an inverter 34. The inverted signal is input to each of the gates of the NMOSs 32c, in the sense amplifiers 28a, 28b, and 28c. An output signal OUT is output from a drain of the PMOS 30b in the sense amplifier 28c.

In the sense amplifier 28c, the size of the NMOS 32b is configured to be greater than that of the NMOS 32a. For example, channel width W of the NMOS 32b is greater than channel width W of the NMOS 32a.

An operation of the source potential comparator circuit 24b will be described below.

When the control signal is at the high level, i.e., the internal circuit is in the operational mode, the NMOSs 32c in the sense amplifiers 28a, 28b, and 28c are turned off. As a result, the sense amplifiers 28a, 28b, and 28c are disabled.

When the sense amplifiers 28a, 28b, and 28c are disabled, output signals of the sense amplifier 28a and 28b, as well as the output signal OUT of the sense amplifier 28c, become high level, regardless of the potential at the source GND′ of the transistors in the internal circuit 12.

On the other hand, when the control signal is at the low level, i.e., when the internal circuit 12 is not in the operational mode, the NMOSs 32c of the sense amplifier 28a, 28b, and 28c are turned on. As a result, the sense amplifiers 28a, 28b, and 28c are enabled.

When the sense amplifiers 28a, 28b, and 28c are enabled, and the potential at the source GND′ and the potential of the ground GND are substantially equal, the NMOSs 32a and 32b of the sense amplifiers 28a and 28b are turned off. Accordingly, the output signals of the sense amplifiers 28a and 28b become a high level. At this time, the NMOSs 32a and 32b of the sense amplifier 28c are turned on. Thus, the output signal OUT of the sense amplifier 28c becomes a low level due to the size difference between the NMOSs 32a and 32b, as described above.

When the potential at the source GND′ rises to the predetermined level that is lower than the highest potential level within a range of the low level necessary for holding the data in the data holding circuit 16, the NMOS 32a of the sense amplifier 28a and the NMOS 32b of the sense amplifier 28b are turned on. As a result, the output signals of the sense amplifiers 28a and 28b become the high and low levels, respectively. This turns off the NMOS 32b of the sense amplifier 28c, so that the output signal OUT of the sense amplifier 28c becomes the high level.

The same configuration shown in FIG. 2 can be applied to the source potential comparator circuit 24a. The configurations of the source potential comparator circuits 24a and 24b are not limited to the configuration shown in FIG. 2, other circuit configurations may be employed to implement similar functions.

According to the following, only a description of an operation of the leakage current cut-off circuit 14b will be made. However, the leakage current cut-off circuit 14a operates in the same manner.

In the semiconductor device 10 according to an exemplary embodiment, the control signal is set to the high level when the internal circuit 12 is in the operational mode (when the paths of the leakage currents are not cut). When the internal circuit 12 is not in the operational mode (when the paths of the leakage currents are cut), the control signal is set to the low level.

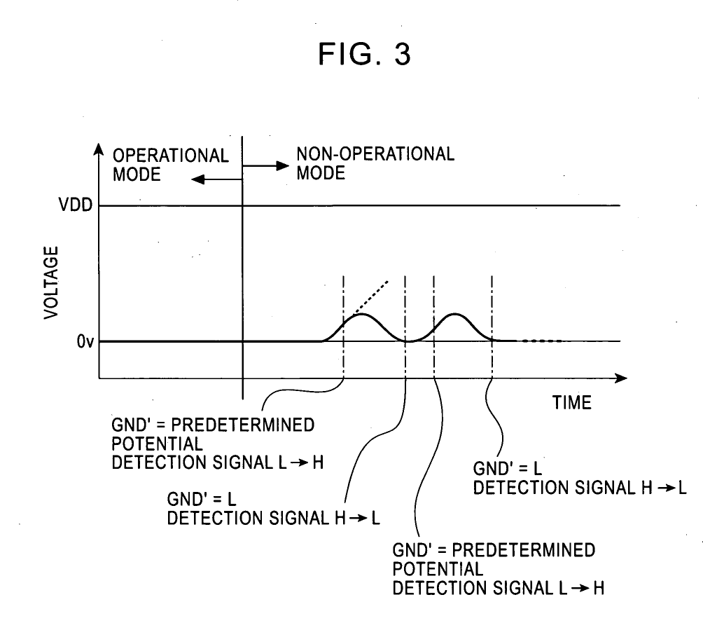

When the control signal is at the high level, the output signal from the OR circuit 18b is also at the high level. At this time, the NMOS 22b is turned on to electrically connect the path between the source GND′ of the ground-side transistors in the internal circuit 12 and the ground GND. Also, the output signal of the source potential comparator circuit 24b becomes the high level. As shown in FIG. 3, while the internal circuit is in the operational mode, the potential at the source GND′ is kept substantially equal to the potential of the ground GND (0 V).

In other words, when the control signal is at the high level, the internal circuit 12 operates in the same manner as a semiconductor device that does not include the leakage current cut-off circuits 14a and 14b therein.

When the control signal becomes the low level, the output signal of the source potential comparator circuit 24b also becomes the low level. Accordingly, the output signal of the OR circuit 18b becomes the low level. At this time, the NMOS 22b is turned off to electrically cut the path between the source GND′ and the ground GND. When the NMOS 22b is turned off, the potential at the source GND′ is brought to a floating state, and gradually rises due to an influence of a noise or the like, as indicated by a solid line in FIG. 3.

Upon detecting that the potential at the source GND′ has risen to the predetermined potential that is lower than the potential necessary for holding the data in the data holding circuits 16, the source potential comparator circuit 24b outputs the high level signal.

In the semiconductor device that does not include the leakage current cut-off circuits 14a and 14b, the potential at the source GND′, which is indicated by the broken line for comparison, gradually rises.

When the output signal of the source potential comparison circuit 24b becomes the high level, the output signal of the OR circuit 18b also becomes the high level. At this time, the NMOS 22b is turned on to electrically connect the path between the source GND′ and the ground GND. Accordingly, the potential at the source GND′ gradually drops as indicated by the solid line in FIG. 3. Upon detecting that the potential at source GND′ has become substantially equal to the potential of the ground GND, the source potential comparator circuit 24b outputs the low level signal.

When the output signal of the source comparator circuit 24b becomes the low level, the output signal of the OR circuit 18b also becomes the low level. This turns off the NMOS 22b, and the path between the source GND′ and the ground GND is electrically cut. Thereafter the above-described operation is repeated.

More specifically, when the control signal is at the low level, and the potential at the source GND′ of the ground-side transistors in the internal circuit 12 rises to the predetermined potential due to the influence of the noise or the like, the operation to lower the potential at the source GND′ to the potential of the ground GND is repeatedly performed.

In the leakage current cut-off circuit 14b, a predetermined potential that is lower than the potential of the ground GND is input to the gate of the NMOS 22b when the output signal of the step-down circuit 20b is at the low level. This makes off-resistance of the NMOS 22b greater than that of the transistors included in the internal circuit 12, thereby significantly reducing the off-leakage current that flows from the power supply VDD to the ground GND.

Also, in the leakage current cut-off circuit 14b, when the potential at the source GND′ of the ground-side transistors in the internal circuit 12 rises to the predetermined potential that is lower than the potential necessary for holding the data in the data holding circuits 16, the NMOS 22b is automatically turned on, and the source GND′ is temporarily electrically connected to the ground GND. This prevents the data held in the data holding circuits 16 from being destroyed without providing an extra area for disposing a data holding circuit or an extra storage device.

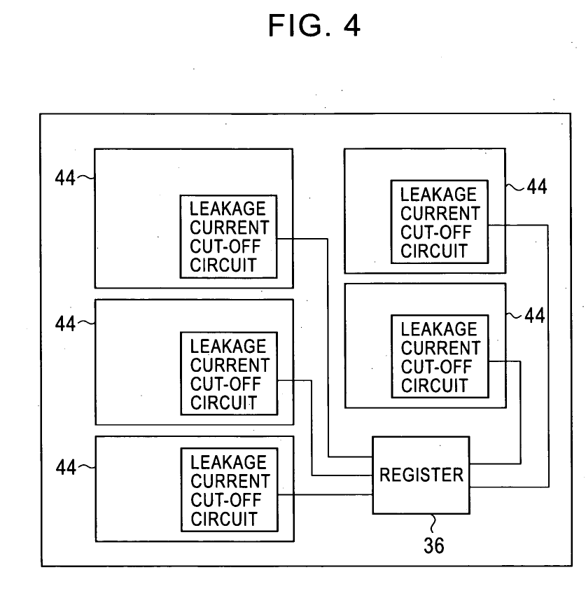

As shown in FIG. 4, an internal circuit may be divided into a plurality of blocks 44, and leakage current cut-off circuits may be provided in each block 44. In such a case, detection signals output from the leakage current cut-off circuit that is provided in each block 44 are periodically sampled, and history data of the sampled results is held in a holding circuit, such as a register 36. This allows a change in the potential at the sources of power-supply side transistors and ground-side transistors to be known, while each block 44 is not in the operational mode.

For example, in the block 44 that is greatly affected by the noise, the detection signal frequently changes. In such a case, a control operation can be optimized in accordance with a state of each block 44. More specifically, when the blocks 44 are not in the operational mode, the control operation by the leakage current cut-off circuit may be suspended on the basis of the history data of the detection signals of the corresponding blocks 44, which is held in the register 36. Alternatively, an ON period of a transistor that electrically connects or cuts the path between the sources of the transistors in the internal circuit and the power supply or the ground may be shortened.

Since the leakage current cut-off circuits 14a and 14b are not target circuits whose leakage currents are to be cut off, current leakage always occurs in the leakage current cut-off circuits 14a and 14b. However, the size and leakage current of the leakage current cut-off circuits 14a and 14b are much smaller than those of the internal circuit 12. Thus, the leakage current of the leakage current cut-off circuits 14a and 14b can be ignored.

According to the various exemplary embodiments described above, the semiconductor device having two leakage current cut-off circuits 14a and 14b. However, a semiconductor device having either the power-supply side leakage current cut-off circuit 14a or the ground-side leakage current cut-off circuit 14b can provide the same advantages. It is thus possible to select the configuration of the semiconductor device in accordance with various circumstances.

Now, a semiconductor device according to another exemplary embodiment of the present invention is described.

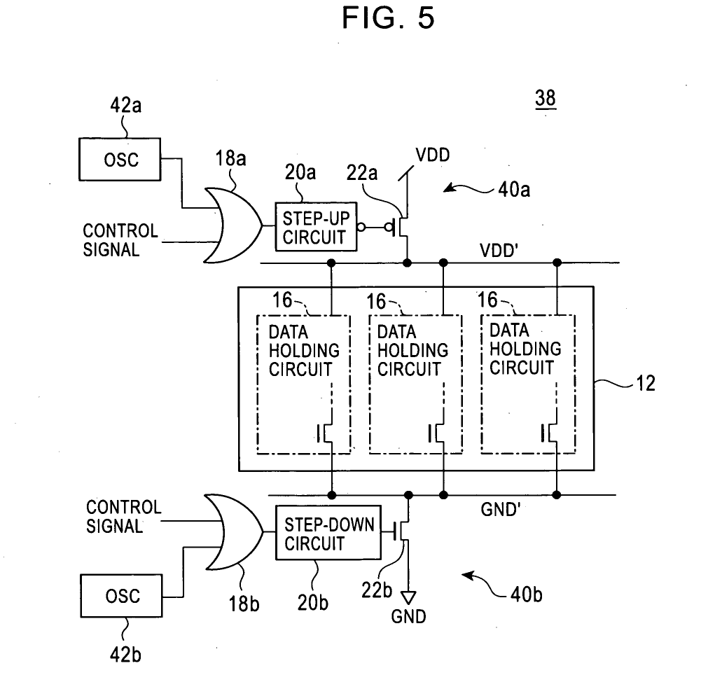

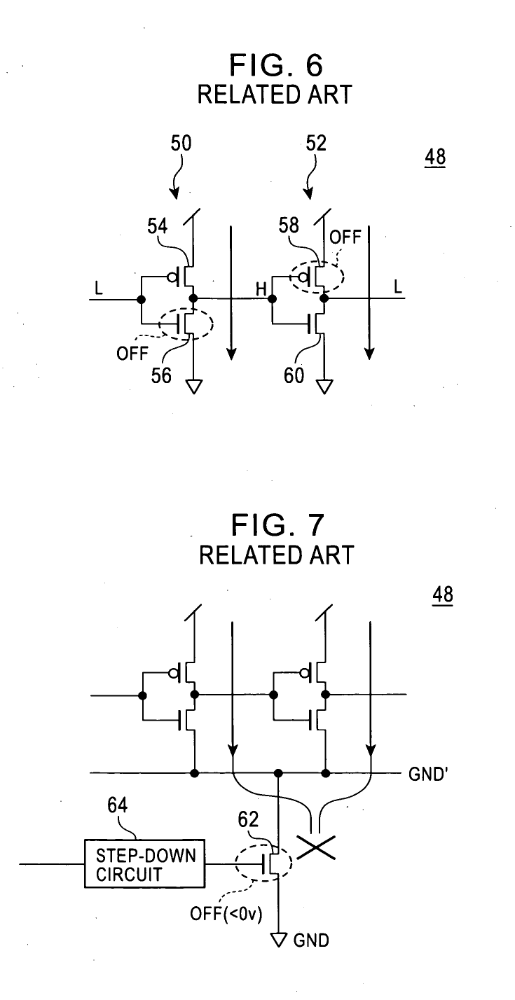

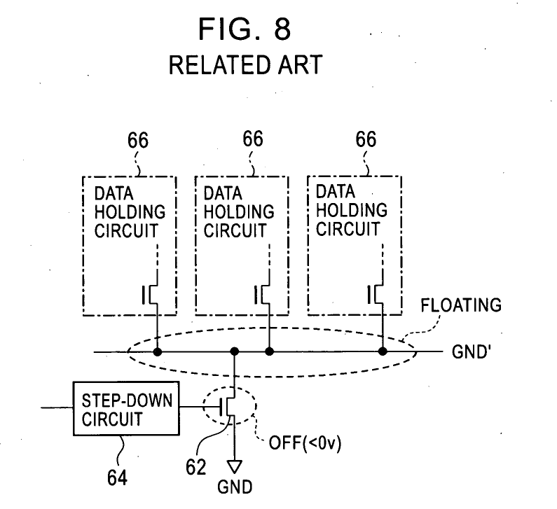

FIG. 5 is a schematic diagram showing a semiconductor device according to another exemplary embodiment of the present invention. A semiconductor device 38 shown in FIG. 5 includes a leakage current cut-off circuit 40a disposed near a power supply, and a leakage current cut-off circuit 40b disposed near a ground. The difference between the semiconductor device 10 shown in FIG. 1 and the semiconductor device 38 shown in FIG. 5 is that the semiconductor device 38 includes ring oscillator circuits (hereinafter, referred to as “OSC”) 42a and 42b instead of source potential comparator circuits 24a and 24b.

More specifically, the leakage current cut-off circuit 40a includes an OR circuit 18a, a step-up circuit 20a, a PMOS 22a, and an OSC 42a. The leakage current cut-off circuit 40b includes an OR circuit 18b, a step-down circuit 20b, an NMOS 22b, and an OSC 42b. Output signals from the OSCs 42a and 42b are input to the OR circuits 18a and 18b, respectively.

The OSC 42a outputs a high level signal for a predetermined time period at predetermined time intervals. The predetermined time interval is shorter than the time required for the potential at a source VDD′ of the transistors in the internal circuit 12 to drop to a predetermined potential that is higher than a potential necessary for holding data in the data holding circuits 16 after the PMOS 22a is turned off such that the path between a power supply VDD and the source VDD′ is cut. The predetermined time period is equivalent to the time required for the potential at the source VDD′ to become substantially equal to the potential of the power supply VDD.

When the output signal of the OSC 42a becomes a high level, an output signal of the OR circuit 18a (a first pulse signal of an exemplary embodiment of the present invention) also becomes the high level, which turns on the PMOS 22a. As a result, the potential at the source VDD′ becomes substantially equal to the potential of the power supply VDD at the predetermined time intervals.

Likewise, the OSC 42b outputs a high level signal for a predetermined time period at predetermined time intervals. The predetermined time interval is shorter than the time required for a potential at the source GND′ of the transistors in the internal circuit 12 to rise to a predetermined potential that is lower than a potential necessary for holding the data in the data holding circuits 16 after the NMOS 22b is turned off such that the path between the source GND′ and the ground GND are cut. The predetermined time period is equivalent to the time required for the potential at the source GND′ to become substantially equal to the potential of the ground GND.

When the output signal of the OSC 42b becomes the high level, the output signal of the OR circuit 18b (a second pulse signal of an exemplary embodiment of the present invention) also becomes the high level, which turns on the NMOS 22b. As a result, the potential at the source GND′ becomes substantially equal to the potential of the ground GND at the predetermined time intervals.

Use of the OSCs 42a and 42b reduces the current consumption compared with a case in which the source potential comparator circuits 24a and 24b are used.

The OR circuit 18a and the OSC 42a constitute a first control circuit. The OR circuit 18b and the OSC 42b constitute a second control circuit. Also, the step-up circuit 20a and the PMOS 22a constitute a first switch. The step-down circuit 20b and the NMOS 22b constitute a second switch. The first and second control circuits and the first and second switches are not limited to the configuration of the embodiment shown in FIG. 5, various configurations can be applied in order to implement similar functions.

Additionally, a pulse signal output from a signal OSC may be commonly utilized by the power-supply-side and the ground-side cut-off circuits. Instead of using the OSCs, it is also possible to use other circuit configurations that have the equivalent functions to the OSCs. A signal corresponding to the output signal of the OSC may be input from outside of the semiconductor device 38.

In the above-described exemplary embodiment, the transistors that have the same threshold voltage values as the transistors included in the internal circuit, the step-up circuit, and the step-down circuit are employed to cut off the path of the leakage current. However, instead of using the step-up circuit and the step-down circuit, transistors may be connected between the sources of the power-supply-side transistors in the internal circuit and the power supply, and between the sources of the ground-side transistors and the ground. The transistors that are used instead of the step-up and step-down circuits are configured to have greater threshold voltage value than the power-supply-side transistors and the ground-side transistors of the internal circuit. In other words, the transistors are less likely to be turned on than the transistors in the internal circuit.

In the exemplary embodiment described above, the semiconductor device having two leakage current cut-off circuits 40a and 40b is described. However, a semiconductor device having either the power-supply-side leakage current cut-off circuit 40a or the ground-side leakage current cut-off circuit 40b can provide similar advantages. It is thus possible to select the configuration of the semiconductor device in accordance with circumstances.

The various exemplary embodiments of present invention are basically as described above.

The semiconductor devices according to the exemplary embodiments of the present invention have been described in detail, however, the exemplary embodiments are not limited to the above-described embodiments. Various improvements and modifications can be made without departing from the spirit and scope of the described exemplary embodiments.

What is claimed is:

1. A semiconductor device, comprising:
an internal circuit having a data holding circuit; and
at least one leakage current cut-off circuit which electrically connects or cuts at least one of a path between a power supply and the internal circuit and a path between a ground and the internal circuit on the basis of a control signal,
the leakage current cut-off circuit for electrically connecting or cutting the path between the power supply and the internal circuit including:
a first switch for electrically connecting or cutting a path between the power supply and a source of a power-supply-side transistor of the internal circuit, on the basis of a first detection signal, and
a first control circuit which, when the internal circuit is out of an operational mode, upon detecting that a potential at the source of the power-supply-side transistor has become substantially equal to a potential of the power supply, causes the first detection signal to become a first state such that the first switch is put into a cut-off state, and which, upon detecting that the potential at the source of the power-supply-side transistor has dropped to a predetermined potential that is higher than a potential necessary for holding data in the data holding circuit, causes the first detection signal to become a second state such that the first switch is put into a connected state, whereas when the internal circuit is in the operational mode, the first control circuit causes the first detection signal to become the second state such that the first switch is put into the connected state, and
the leakage current cut-off circuit for electrically connecting or cutting the path between the ground and the internal circuit including:
a second switch for electrically connecting or cutting a path between a source of a ground-side transistor of the internal circuit and the ground on the basis of a second detection signal, and
a second control circuit which, when the internal circuit is out of the operational mode, upon detecting that a potential at the source of the ground-side transistor has become substantially equal to a potential of the ground, causes the second detection signal to become the first state such that the second switch is put into the cut-off state, and which, upon detecting that the potential at the source of the ground-side transistor has risen to a predetermined potential lower than a potential necessary for holding the data in the data holding circuit, causes the second detection signal to become the second state such that the second switch is put into the connected state, whereas when the internal circuit is in the operational mode, the second control circuit causes the second detection signal to become the second state such that the second switch is put into the connected state.

2. The semiconductor device according to claim 1, the first switch including:
a step-up circuit for receiving the first detection signal and outputting a signal having a stepped-up potential that is equal to or higher than that of the power supply, and
a first transistor for electrically connecting or cutting the path between the power supply and the source of the power-supply-side transistor on the basis of an output signal of the step-up circuit, and
the second switch including:
a step-down circuit for receiving the second detection signal and outputting a signal having a stepped-down potential that is equal to or lower than the potential of the ground, and
a second transistor for electrically connecting or cutting the path between the source of the ground-side transistor and the ground on the basis of an output signal of the step-down circuit.

3. The semiconductor device according to claim 1,
the first switch including a first transistor, having a threshold voltage higher than that of the power-supply-side transistor, for electrically connecting or cutting the path between the power supply and the source of the power-supply-side transistor on the basis of the first detection signal, and
the second switch including a second transistor, having a threshold voltage higher than that of the ground-side transistor, for electrically connecting or cutting the path between the source of the ground-side transistor and the ground on the basis of the second detection signal.

4. The semiconductor device according to claim 1, wherein the internal circuit is divided into a predetermined number of blocks, and at least one leakage current cut-off circuit for electrically connecting or cutting at least one of the path between the power supply and the internal circuit and the path between the ground is disposed in each of the blocks, the semiconductor device further comprising:
a holding circuit for holding history data of the first detection signal and the second detection signal output from the corresponding leakage current cut-off circuits in each of the blocks, wherein
the first control circuit in each of the blocks performs a control operation such that the first switch is put into the connected state or the cut-off state on the basis of the history data of the first detection signal, held in the holding circuit, of the corresponding block, and
the second control circuit in each of the blocks performs a control operation such that the second switch is put into the connected state or the cut-off state on the basis of the history data of the second detection signal, held in the holding circuit, of the corresponding block.

5. A semiconductor device, comprising:
an internal circuit having a data holding circuit, and
at least one leakage current cut-off circuit which electrically connects or cuts at least one of a path between a power supply and the internal circuit and a path between a ground and the internal circuit on the basis of a control signal,
the leakage current cut-off circuit for electrically connecting or cutting the path between the power supply and the internal circuit including:
a first switch for electrically connecting or cutting a path between the power supply and a source of a power-supply-side transistor of the internal circuit on the basis of a first pulse signal, and
a first control circuit which, when the internal circuit is out of an operational mode, puts the first switch into a connected state for a first predetermined time period at first predetermined time intervals,
wherein the first time interval is shorter than the time required for a potential at the source of the power-supply-side transistor to drop to a predetermined potential that is higher than a potential necessary for holding data in the data holding circuit after the first control circuit causes the first pulse signal to become a first state such that the first switch is put into a cut-off state, and
the first time period is equivalent to the time required for the potential at the source of the power-supply-side transistor to become substantially equal to a potential of the power supply after the first control circuit causes the first pulse signal to become a second state,
whereas when the internal circuit is in the operational mode, the first control circuit causes the first pulse signal to become the second state such that the first switch is put into the connected state, and
the leakage current cut-off circuit for electrically connecting or cutting the path between the ground and the internal circuit including:
a second switch for electrically connecting or cutting a path between a source of a ground-side transistor of the internal circuit and the ground on the basis of a second pulse signal, and
a second control circuit which, when the internal circuit is out of the operational mode, puts the second switch into the connected state for a second predetermined time period at second predetermined time intervals,
wherein the second predetermined time interval is shorter than the time required for a potential at the source of the ground-side transistor to rise to a predetermined potential that is lower than a potential necessary for holding the data in the data holding circuit after the second control circuit causes the second pulse signal to become the first state such that the second switch is put into the cut-off state,
the second time period is equivalent to the time required for the potential at the source of the ground-side transistor to become substantially equal to a potential of the ground after the second control circuit causes the second pulse signal to become the second state,
whereas when the internal circuit is in the operational mode, the second control signal causes the second pulse signal to become the second state such that the second switch is put into the connected state.

6. The semiconductor device according to claim 5,
the first switch including:
a step-up circuit for receiving the first pulse signal and outputting a signal having a stepped-up potential that is equal to or higher than that of the power supply, and
a first transistor for electrically connecting or cutting the path between the power supply and the source of the power-supply-side transistor on the basis of an output signal of the step-up circuit, and
the second switch including:
a step-down circuit for receiving the second pulse signal and outputting a signal having a stepped-down potential that is equal to or lower than that of the ground, and
a second transistor for electrically connecting or cutting the path between the source of the ground-side transistor and the ground on the basis of an output signal of the step-down circuit.

7. The semiconductor device according to claim 5,
the first switch including a first transistor, having a threshold voltage higher than that of the power-supply-side transistor, for electrically connecting or cutting the path between the power supply and the source of the power-supply-side transistor on the basis of the first pulse signal, and
the second switch including a second transistor, having a threshold voltage higher than that of the ground-side transistor, for electrically connecting or cutting the path between the source of the ground-side transistor and the ground on the basis of the second pulse signal.
